(19) United States
(12) Patent Application Publication
(10) Pub. No.: US 2024/0321839 A1
(43) Pub. Date: Sep. 26, 2024

(54) SEMICONDUCTOR PACKAGE

(71) Applicant: Samsung Electronics Co., Ltd., Suwon-si (KR)

(72) Inventors: Kyungdon Mun, Suwon-si (KR); Kyounglim Suk, Suwon-si (KR); Jihwang Kim, Suwon-si (KR)

(21) Appl. No.: 18/530,542

(22) Filed: Dec. 6, 2023

(30) Foreign Application Priority Data
Mar. 24, 2023 (KR) 10-2023-0039308

(51) Int. Cl. H01L 25/10; H01L 23/00; H01L 23/31; H01L 23/367; H01L 23/498; H10B 80/00

(52) U.S. Cl. CPC H01L 25/105; H01L 23/3107; H01L 23/367; H01L 23/49822; H01L 24/16; H01L 24/32; H01L 24/73; H10B 80/00; H01L 2224/16227; H01L 2224/16238; H01L 2224/32225; H01L 2224/32245; H01L 2224/73253; H01L 2225/1023; H01L 2225/1041; H01L 2225/1058; H01L 2225/1094; H01L 2924/1431; H01L 2924/1434

(57) ABSTRACT

A semiconductor package includes a first redistribution structure including a first redistribution insulating layer and a first redistribution pattern, a first lower semiconductor device mounted on the first redistribution structure, a molding layer surrounding the first lower semiconductor device on the first redistribution structure, a plurality of vertical connection conductors in the molding layer and electrically connected to the first redistribution pattern, a heat dissipation plate disposed on an upper surface of the first lower semiconductor device, and a plurality of upper semiconductor devices disposed on the molding layer and on the first lower semiconductor device, each of the plurality of upper semiconductor devices vertically overlapping a different respective region of the first lower semiconductor device.

### CROSS-REFERENCE TO RELATED APPLICATION

This application is based on and claims priority under 35 U.S.C. § 119 to Korean Patent Application No. 10-2023-0039308, filed on Mar. 24, 2023, in the Korean Intellectual Property Office, the disclosure of which is incorporated by reference herein in its entirety.

### BACKGROUND

The inventive concept relates to a semiconductor package.

According to the rapid development of the electronics industry and user demands, electronic devices have been further miniaturized, multi-functionalized, and increased in capacity. Accordingly, a semiconductor package including a plurality of semiconductor chips is required. For example, a method of mounting several types of semiconductor chips side by side on one package substrate or stacking semiconductor chips and/or packages on one package substrate may be used.

### SUMMARY

The inventive concept provides a semiconductor package including a plurality of semiconductor devices.

In accordance with an aspect of the disclosure, a semiconductor package includes a first redistribution structure including a first redistribution insulating layer and a first redistribution pattern; a first lower semiconductor device mounted on the first redistribution structure; a molding layer surrounding the first lower semiconductor device on the first redistribution structure; a plurality of vertical connection conductors in the molding layer, the plurality of vertical connection conductors being electrically connected to the first redistribution pattern; a heat dissipation plate on an upper surface of the first lower semiconductor device; and a plurality of upper semiconductor devices on the molding layer and on the first lower semiconductor device, each of the plurality of upper semiconductor devices vertically overlapping a different respective region of the first lower semiconductor device, wherein the plurality of upper semiconductor devices are laterally spaced apart from the heat dissipation plate such that a gap is formed between each of the plurality of upper semiconductor devices and the heat dissipation plate, and wherein each of the plurality of upper semiconductor devices is vertically overlapped with a corresponding vertex among vertices of the upper surface of the first lower semiconductor device.

In accordance with an aspect of the disclosure, a semiconductor package includes a lower package including a lower semiconductor device and a molding layer surrounding the lower semiconductor device; a plurality of upper semiconductor devices on the lower package, each of the plurality of upper semiconductor devices vertically overlapping a different respective region of the lower semiconductor device; and a heat dissipation plate on an upper surface of the lower semiconductor device, the heat dissipation plate laterally spaced apart from each of the plurality of upper semiconductor devices with a gap therebetween, wherein the lower semiconductor device comprises at least one logic chip, and wherein the plurality of upper semiconductor devices comprise four memory chips vertically overlapping four vertices of the upper surface of the lower semiconductor device, respectively.

In accordance with an aspect of the disclosure, a semiconductor package includes a first redistribution structure including a first redistribution insulating layer and a first redistribution pattern; a lower semiconductor device mounted on a first region of the first redistribution structure; a plurality of vertical connection conductors on a second region of the first redistribution structure, the plurality of vertical connection conductors being connected to the first redistribution pattern; a molding layer on the first redistribution structure and surrounding the lower semiconductor device and the plurality of vertical connection conductors; a second redistribution structure on the molding layer and the lower semiconductor device, the second redistribution structure including a second redistribution insulating layer and a second redistribution pattern, wherein the second redistribution pattern is electrically connected to the first redistribution pattern through the plurality of vertical connection conductors; a heat plate contact within the second redistribution insulating layer and in contact with an upper surface of the lower semiconductor device; a plurality of upper semiconductor devices mounted on the second redistribution structure and each vertically overlapping a different respective region of the lower semiconductor device; and a heat dissipation plate attached on the heat plate contact and spaced apart from each of the plurality of upper semiconductor devices in a lateral direction with a gap therebetween, wherein the upper surface of the lower semiconductor device includes four vertices, wherein the plurality of upper semiconductor devices include four semiconductor devices vertically overlapping the four vertices, respectively, of the upper surface of the lower semiconductor device, wherein the lower semiconductor device comprises a logic chip, and wherein the plurality of upper semiconductor devices include memory chips.

In accordance with an aspect of the disclosure, a method of manufacturing a semiconductor package includes forming a first redistribution structure on a substrate, the first redistribution structure having a first region and a second region surrounding the first region in plan view; forming vertical connection conductors on the first redistribution structure in the second region of the first redistribution structure; mounting a first lower semiconductor device on the first redistribution structure, in the first region of the first redistribution structure; forming a molding layer covering the first lower semiconductor device and the vertical connection conductors; removing a portion of the molding layer to expose the first lower semiconductor device and the vertical connection conductors; forming a second redistribution structure on an upper surface of the molding layer and on an upper surface of the first lower semiconductor device; forming a through hole in the second redistribution structure, in a region of the second redistribution structure vertically overlapping the first region of the first redistribution structure; forming a heat plate contact in the through hole; and mounting a plurality of upper semiconductor devices on the second redistribution structure, in a region of the second redistribution structure vertically overlapping the second region of the first redistribution structure.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to embodiments;

FIG. 2 is a layout diagram of main components of the semiconductor package of FIG. 1;

FIGS. 3A to 3G are cross-sectional views illustrating a method of manufacturing a semiconductor package according to embodiments;

FIG. 4 is a cross-sectional view of a semiconductor package according to embodiments;

FIG. 5 is a cross-sectional view of a semiconductor package according to embodiments;

FIG. 6 is a cross-sectional view of a semiconductor package according to embodiments;

FIG. 7 is a cross-sectional view of a semiconductor package according to embodiments;

FIG. 8 is a cross-sectional view of a semiconductor package according to embodiments;

FIG. 9 is a cross-sectional view of a semiconductor package according to embodiments;

FIG. 10 is a cross-sectional view of a semiconductor package according to embodiments;

FIG. 11 is a cross-sectional view of a semiconductor package according to embodiments;

FIG. 12 is a cross-sectional view of a semiconductor package according to embodiments;

FIG. 13 is a cross-sectional view of a semiconductor package according to embodiments;

FIG. 14 is a cross-sectional view of a semiconductor package according to embodiments;

FIG. 15 is a layout diagram illustrating a main configuration of a semiconductor package according to embodiments; and

FIG. 16 is a layout diagram illustrating a main configuration of a semiconductor package according to embodiments.

### DETAILED DESCRIPTION OF THE EMBODIMENTS

Hereinafter, embodiments of the technical idea of the inventive concept will be described in detail with reference to the accompanying drawings. The same reference numerals are used for the same components in the drawings, and duplicate descriptions thereof are omitted.

In this specification, the vertical direction is defined as the Z direction, and a horizontal or lateral direction may be defined as a direction perpendicular to the Z direction. The first horizontal direction or first lateral direction may be referred to as the X direction, and the second horizontal direction or second lateral direction may be referred to as the Y direction. The first lateral direction may intersect the second lateral direction. For example, the first lateral direction may be perpendicular to the second lateral direction. A vertical level may refer to a height level in a vertical direction, and a horizontal width may refer to a length in a horizontal direction. A dimension of a component may refer to length in a horizontal direction, length in a vertical direction, and/or planar area.

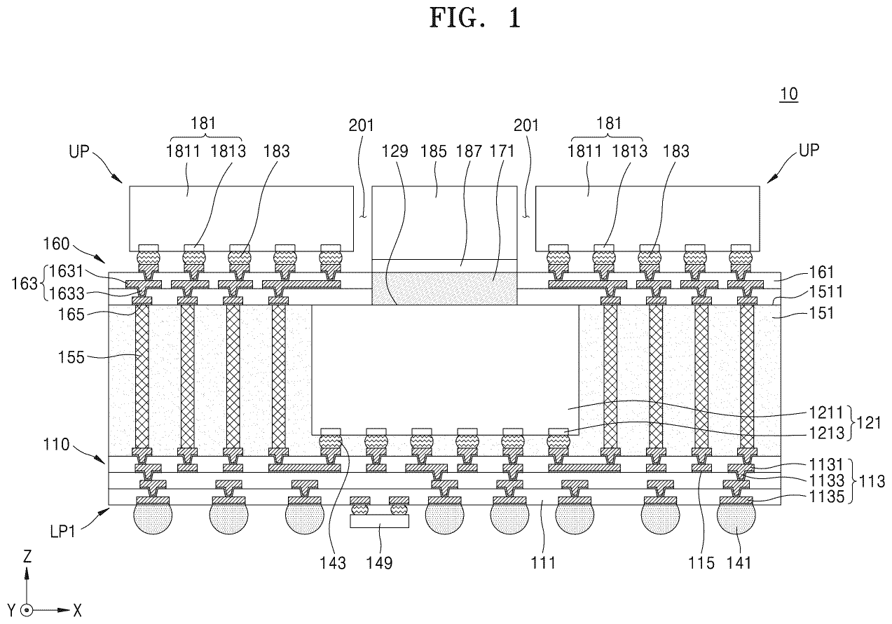

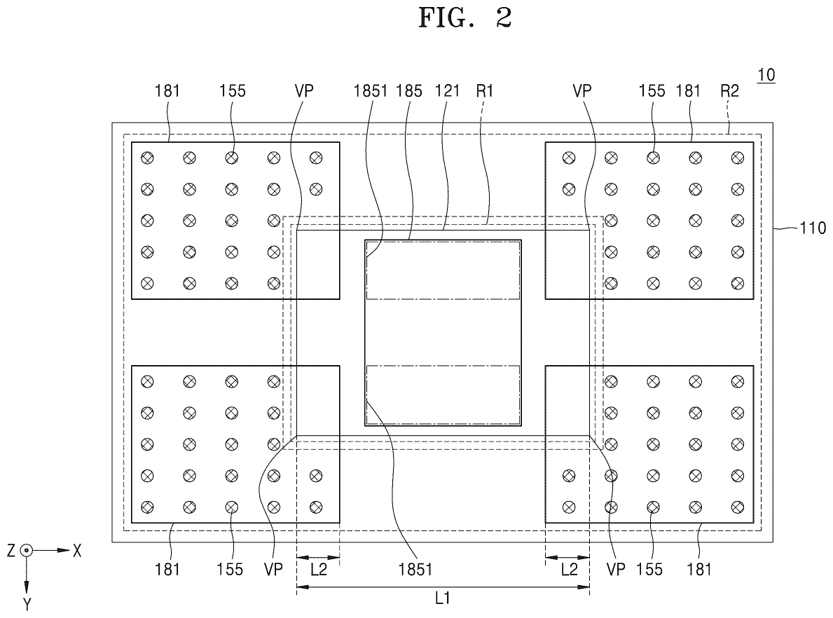

FIG. 1 is a cross-sectional view of a semiconductor package 10 according to embodiments. FIG. 2 is a layout diagram of the main components of the semiconductor package 10 of FIG. 1.

Referring to FIGS. 1 and 2, the semiconductor package 10 may include a lower package LP1 and a plurality of upper packages UP. The semiconductor package 10 may be a package-on-package type package in which the upper packages UP are stacked on or attached to the lower package LP1.

The lower package LP1 may include a first redistribution structure 110, a first lower semiconductor device 121, a molding layer 151, vertical connection conductors 155, a second redistribution structure 160, and a heat dissipation pad structure 171 (e.g., a heat plate contact). The lower package LP1 may be a package having a fan-out structure. A footprint of the first redistribution structure 110 may be greater than that of the first lower semiconductor device 121. A footprint of the first redistribution structure 110 may be the same as that of the semiconductor package 10.

The first redistribution structure 110 may be a package substrate for attaching mounting components such as the first lower semiconductor device 121. The first redistribution structure 110 may have a plate shape or a panel shape. The first redistribution structure 110 may include upper and lower surfaces opposite to each other, and the upper and lower surfaces of the first redistribution structure 110 may each be a plane perpendicular to a vertical direction (e.g., Z direction).

The first redistribution structure 110 may include a plurality of first redistribution insulating layers 111 and a first conductive redistribution pattern 113.

The plurality of first redistribution insulating layers 111 may be stacked in a vertical direction (e.g., a Z direction). The plurality of first redistribution insulating layers 111 may be formed of an insulating polymer, epoxy, or a combination thereof. For example, each of the plurality of first redistribution insulating layers 111 may be formed of photo imageable dielectric (PID) or photosensitive polyimide (PSPI).

The first conductive redistribution pattern 113 may include first conductive layers 1131, first conductive via patterns 1133, and external connection pads 1135. Each of the first conductive layers 1131 may extend in a horizontal direction (e.g., an X direction and/or a Y direction) and may be disposed at different vertical levels to form a multilayer structure. The first conductive layers 1131 may be disposed on any one of upper and lower surfaces of each of the plurality of first redistribution insulating layers 111. For example, the first conductive layers 1131 may include line patterns extending in a line shape along any one surface of the upper and lower surfaces of any one of the plurality of first redistribution insulating layers 111. The first conductive layer 1131 provided on the uppermost insulating layer among the plurality of first redistribution insulating layers 111 may include pads to which first chip connection bumps 143 are attached and pads to which the vertical connection conductors 155 are attached. The first conductive via patterns 1133 may extend in a vertical direction (e.g., a Z direction) through at least one of the plurality of first redistribution insulating layers 111. The first conductive via patterns 1133 electrically may connect the first conductive layers 1131 disposed at different vertical levels or electrically may connect the first conductive layer 1131 and the external connection pad 1135.

The external connection pads 1135 may be disposed at the lower surface of the first redistribution structure 110 and come into contact with the external connection terminal 141. The external connection pads 1135 may be electrically connected to the first lower semiconductor device 121 and/or the vertical connection conductors 155 through the first conductive redistribution pattern 113. In embodiments, when viewed in cross section, the external connection pads 1135 may have a rectangular shape.

For example, the first conductive redistribution pattern 113 may include, for example, a metal such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

At least some of the plurality of first conductive layers 1131 may be integrally formed with some of the plurality of first conductive via patterns 1133. For example, some of the plurality of first conductive layers 1131 may be integrally formed with a corresponding first conductive via pattern 1133 contacting a lower side thereof. For example, the first conductive layer 1131 and the first conductive via pattern 1133 connected to each other may be formed together through an electroplating process.

In embodiments, each of the plurality of first conductive via patterns 1133 may have a tapered shape in which a horizontal width narrows and extends in a direction from an upper side to a lower side thereof. The horizontal width of each of the plurality of first conductive via patterns 1133 may gradually decrease as it approaches the upper surface of the external connection pad 1135.

A seed metal layer 115 may extend along the surface of the first conductive layer 1131 and the surface of the first conductive via pattern 1133. For example, the seed metal layer 115 may be disposed between the bottom surface of the first conductive layer 1131 and the first redistribution insulating layer 111, and may be disposed between each of the sidewall and the bottom surface of the first conductive via pattern 1133 and the first redistribution insulating layer 111. In addition, the seed metal layer 115 may be disposed between the first conductive via pattern 1133 and the external connection pad 1135. In addition, the seed metal layer 115 may be disposed between the external connection pad 1135 and the external connection terminal 141 and extend along a lower surface of the external connection pad 1135. For example, the seed metal layer 115 may include at least one of copper (Cu), titanium (Ti), titanium tungsten (TiW), titanium nitride (TiN), tantalum (Ta), tantalum nitride (TaN), chromium (Cr), and aluminum (Al). For example, the seed metal layer 115 may be formed through a physical vapor deposition process such as sputtering.

In embodiments, the external connection pad 1135 may have a rectangular shape when viewed in cross section. In embodiments, a lower surface of the external connection pad 1135 may be substantially coplanar with a lower surface of the first redistribution insulating layer 111. For example, the external connection pad 1135 may be formed through an electroplating process. In embodiments, the external connection pad 1135 may include a plurality of metal layers stacked in a vertical direction (e.g., Z direction).

The external connection terminals 141 may be attached to the external connection pads 1135 of the first redistribution structure 110. The external connection terminals 141 may be configured to electrically and physically connect the first redistribution structure 110 to an external device. The external connection terminals 141 may be formed from, for example, solder balls or solder bumps.

One or more passive components 149 may be attached to the lower side of the first redistribution structure 110. The passive components 149 may be attached to the lower side of the first redistribution structure 110 through bumps made of solder.

The first redistribution structure 110 may include a first region R1 (see, e.g., FIG. 2) and a second region R2 spaced apart from each other. The first region R1 and the second region R2 may be regions provided on the upper surface of the first redistribution structure 110, and when viewed in a plan view, may be spaced apart in a horizontal direction (e.g., an X direction and/or a Y direction). The first region R1 and the second region R2 of the first redistribution structure 110 may be referred to as the first region and the second region of the lower package LP1, respectively. For example, the first region R1 may be a region surrounded by the second region R2 as shown in FIG. 2.

The first lower semiconductor device 121 may be mounted on the first region R1 of the first redistribution structure 110. The first region R1 of the first redistribution structure 110 is a region vertically overlapped with the first lower semiconductor device 121, and a footprint of first region R1 of the first redistribution structure 110 may be substantially the same as that of the first lower semiconductor device 121.

The first lower semiconductor device 121 may be electrically and physically connected to the first conductive redistribution pattern 113 of the first redistribution structure 110 through the first chip connection bumps 143. Each of the first chip connection bumps 143 may be disposed between the first lower semiconductor device 121 and the first conductive layer 1131 provided on the uppermost insulating layer of the first redistribution insulating layer 111. The first chip connection bumps 143 may include solder bumps.

The first lower semiconductor device 121 may include a first lower semiconductor substrate 1211 and first lower connection pads 1213. The first lower semiconductor substrate 1211 may be formed from a semiconductor wafer. The first lower semiconductor substrate 1211 may include, for example, silicon (Si). The first lower semiconductor substrate 1211, for example, may include a semiconductor element, such as germanium (Ge), or a compound semiconductor, such as silicon carbide (SiC), gallium arsenide (GaAs), indium arsenide (InAs), and indium phosphide (InP). The first lower semiconductor substrate 1211 may include a conductive region, for example, a well doped with an impurity or a structure doped with an impurity. The first lower semiconductor device 121 may include a semiconductor element layer provided in and/or on an active surface (e.g., a lower surface of the first lower semiconductor substrate 1211) of the first lower semiconductor substrate 1211. A semiconductor element layer of the first lower semiconductor device 121 may include individual elements. The individual elements may include, for example, transistors. The individual elements may include microelectronic devices such as a metal-oxide-semiconductor field effect transistors (MOSFET), a system large scale integration (LSI), an image sensor such as a CMOS imaging sensor (CIS), a micro-electro-mechanical system (MEMS), an active element, a passive element, and the like. The first lower connection pads 1213 may be provided on the lower surface of the first lower semiconductor device 121 and may directly contact the first chip connection bumps 143.

The first lower semiconductor device 121 may include a semiconductor chip and/or a package including at least one semiconductor chip. In embodiments, the first lower semiconductor device 121 may have a three-dimensionally stacked structure including a plurality of semiconductor chips mutually stacked in a vertical direction (e.g., Z direction). In embodiments, the first lower semiconductor device 121 may include a plurality of semiconductor chips arranged in a horizontal direction (e.g., X direction and/or Y direction).

The molding layer 151 may be disposed on the first redistribution structure 110. The molding layer 151 may cover at least a portion of the first lower semiconductor device 121 and an upper surface of the first redistribution structure 110. The molding layer 151 may extend along sidewalls of the first lower semiconductor device 121 and surround the sidewalls of the first lower semiconductor device 121. The molding layer 151 may not cover the upper surface 129 of the first lower semiconductor device 121. In embodiments, the upper surface 1511 of the molding layer 151 may be coplanar with the upper surface 129 of the first lower semiconductor device 121. Furthermore, the molding layer 151 may fill a gap between the first lower semiconductor device 121 and the first redistribution structure 110 and may surround sidewalls of the first chip connection bumps 143.

For example, the molding layer 151 may include an epoxy-based molding resin or a polyimide-based molding resin. In embodiments, the molding layer 151 may include an epoxy molding compound.

The vertical connection conductors 155 may be disposed on the second region R2 of the first redistribution structure 110. The vertical connection conductors 155 may be configured to electrically connect the first conductive redistribution pattern 113 of the first redistribution structure 110 to the second conductive redistribution pattern 163 of the second redistribution structure 160. The vertical connection conductors 155 may pass through the molding layer 151 in a vertical direction (e.g., Z direction). The lower portion of each of the vertical connection conductors 155 may directly contact the first conductive layer 1131 provided on the uppermost insulating layer among the plurality of the first redistribution insulating layers 111, and the upper portion of each of the vertical connection conductors 155 may directly contact the second conductive redistribution pattern 163. In embodiments, upper surfaces of the vertical connection conductors 155 may be coplanar with the upper surface 1511 of the molding layer 151. The vertical connection conductors 155 may include, for example, copper (Cu). When viewed in a plan view, the vertical connection conductors 155 may be arranged to surround the first lower semiconductor device 121. When viewed in a plan view, the vertical connection conductors 155 may be arranged along an imaginary closed-loop line surrounding the first lower semiconductor device 121.

The second redistribution structure 160 may be disposed on the molding layer 151 and the first lower semiconductor device 121. The second redistribution structure 160 may at least partially cover the upper surface 1511 of the molding layer 151 and may partially cover the upper surface 129 of the first lower semiconductor device 121. In embodiments, the footprint of the second redistribution structure 160 may be the same as that of the first redistribution structure 110. In embodiments, a sidewall of the second redistribution structure 160 may be aligned in a vertical direction (e.g., Z direction) with corresponding sidewalls of the molding layer 151 and corresponding sidewalls of the first redistribution structure 110.

The second redistribution structure 160 may include a plurality of second redistribution insulating layers 161 and a second conductive redistribution pattern 163.

The plurality of second redistribution insulating layers 161 may be mutually stacked in a vertical direction (e.g., a Z direction). The plurality of second redistribution insulating layers 161 may be formed of an insulating polymer, epoxy, or a combination thereof. For example, each of the plurality of second redistribution insulating layers 161 may be formed from PID or PSPI.

The second conductive redistribution pattern 163 may include second conductive layers 1631 and second conductive via patterns 1633. The second conductive layers 1631 may be disposed on any one surface of the upper and lower surfaces of any one of the plurality of second redistribution insulating layers 161. The second conductive layers 1631 may be disposed at different vertical levels to form a multilayer structure. For example, the second conductive layers 1631 may include a line pattern extending in a line shape along the upper or lower surface of any one of the plurality of second redistribution insulating layers 161. The second conductive layer 1631 provided on the uppermost insulating layer among the plurality of second redistribution insulating layers 161 may include pads to which the connection terminals 183 are attached. Among the second conductive layers 1631, the lowermost second conductive layer 1631 may include pads attached to the vertical connection conductors 155. The second conductive via patterns 1633 may extend in a vertical direction (e.g., a Z direction) through at least one insulating layer among the plurality of second redistribution insulating layers 161. The second conductive via patterns 1633 may electrically connect between adjacent second conductive layers 1631 disposed at different vertical levels, or may electrically connect between the second conductive layer 1631 and the vertical connection conductor 155. For example, the second conductive redistribution pattern 163 may be or include, for example, a metal such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

At least some of the plurality of second conductive layers 1631 may be integrally formed with some of the plurality of second conductive via patterns 1633. For example, some of the plurality of second conductive layers 1631 may be integrally formed with a corresponding second conductive via pattern 1633 contacting a lower side thereof. For example, the second conductive layer 1631 and the second conductive via pattern 1633 connected to each other may be formed together through an electroplating process. A seed metal layer 165 may be disposed on the surface of the second conductive layer 1631 and the surface of the second conductive via pattern 1633. For example, the seed metal layer 165 may be disposed between the bottom surface of the second conductive layer 1631 and the second redistribution insulating layer 161, and may be disposed between each of the sidewall and the bottom surface of the second conductive via pattern 1633 and the second redistribution insulating layer 161. For example, the seed metal layer 165 may include at least one of copper (Cu), titanium (Ti), titanium tungsten (TiW), titanium nitride (TiN), tantalum (Ta), tantalum nitride (TaN), chromium (Cr), and aluminum (Al).

In embodiments, each of the plurality of second conductive via patterns 1633 may have a tapered shape in which a horizontal width narrows from an upper side to a lower side thereof. In other words, the horizontal width of each of the plurality of second conductive via patterns 1633 may gradually decrease as it is closer to the upper surface 1511 of the molding layer 151 or the upper surface of the vertical connection conductor 155.

The heat dissipation pad structure 171 (e.g., the heat plate contact) may contact the upper surface 129 of the first lower semiconductor device 121. The heat dissipation pad structure 171 is thermally coupled to the first lower semiconductor device 121, and may not be electrically connected to the first lower semiconductor device 121, the second conductive redistribution pattern 163, and the vertical connection conductors 155. The heat dissipation pad structure 171 may vertically penetrate the second redistribution insulating layer 161 and directly contact the upper surface 129 of the first lower semiconductor device 121. The heat dissipation pad structure 171 may be a thermally conductive contact or block having an enlarged pad shape. The heat dissipation pad structure 171 may extend along a portion of the upper surface 129 of the first lower semiconductor device 121 and cover a portion of the upper surface 129 of the first lower semiconductor device 121. For example, a portion of the upper surface 129 of the first lower semiconductor device 121 may directly contact the heat dissipation pad structure 171, and another portion of the upper surface 129 of the first lower semiconductor device 121 may directly contact the second redistribution insulating layer 161.

It will be understood that when an element is referred to as “contacting” or “in contact with” another element (or using any form of the word “contact”), there are no intervening elements present at the point of contact.

In embodiments, the heat dissipation pad structure 171 may be disposed in a through hole of the second redistribution insulating layer 161 of the second redistribution structure 160, and may at least partially fill the through hole of the second redistribution insulating layer 161 of the second redistribution structure 160. For example, the heat dissipation pad structure 171 may entirely fill the through hole of the second redistribution insulating layer 161, and may extend from the vertical level of the lower surface of the second redistribution insulating layer 161 to the vertical level of the upper surface of the second redistribution insulating layer 161.

The heat dissipation pad structure 171 may include a material having excellent thermal conductivity, for example, metal. In embodiments, the heat dissipation pad structure 171 may include copper (Cu) or aluminum (Al). The heat dissipation pad structure 171 may function to transfer heat generated from the first lower semiconductor device 121 to the outside of the semiconductor package 10 and/or to the heat dissipation plate 185. In embodiments, the heat dissipation pad structure 171 may be formed together with the second conductive redistribution pattern 163 of the second redistribution structure 160 through the same metal interconnect process. In this case, the material and/or material composition of the heat dissipation pad structure 171 may be substantially the same as the material and/or material composition of the second conductive redistribution pattern 163. In embodiments, the heat dissipation pad structure 171 may be formed through a process different from the process of forming the second conductive redistribution pattern 163 of the second redistribution structure 160. In embodiments, a material and/or material composition of the heat dissipation pad structure 171 may be different from a material and/or material composition of the second conductive redistribution pattern 163.

A plurality of upper packages UP may be mounted on the second redistribution structure 160 and spaced apart from each other. Each upper package UP includes an upper semiconductor device 181 mounted on a second redistribution structure 160. A plurality of upper semiconductor devices 181 spaced apart from each other in a lateral direction (e.g., X direction and/or Y direction) may be provided on the second redistribution structure 160. Each upper semiconductor device 181 may include a semiconductor chip and/or a package including the semiconductor chip. For example, each upper semiconductor device 181 may include a semiconductor substrate 1811 and chip pads 1813. The chip pads 1813 of each upper semiconductor device 181 may be electrically and physically connected to the second conductive redistribution pattern 163 of the second redistribution structure 160 through the connection terminals 183.

In embodiments, the first lower semiconductor device 121 and the upper semiconductor devices 181 may include different types of semiconductor chips. The first lower semiconductor device 121 may be electrically connected to each upper semiconductor device 181 through the first conductive redistribution pattern 113 of the first redistribution structure 110, the vertical connection conductors 155, and the second conductive redistribution pattern 163 of the second redistribution structure 160. The first lower semiconductor device 121 and the upper semiconductor devices 181 may include any one or more of a memory chip, a logic chip, a System on Chip (SoC), a power management integrated circuit (PMIC) chip, and a radio frequency integrated circuit (RFIC) chip. The memory chip may include a dynamic random access memory (DRAM) chip, a static random access memory (SRAM) chip, a magnetoresistive random-access memory (MRAM) chip, a NAND flash memory chip, and/or a high bandwidth memory (HBM) chip. The logic chip may include an application processor (AP), a microprocessor, a central processing unit (CPU), a controller, and/or an application specific integrated circuit (ASIC). For example, the SoC may include at least two circuits among a logic circuit, a memory circuit, a digital integrated circuit (IC), a radio frequency integrated circuit (RFIC), and an input/output circuit.

The heat dissipation plate 185 may vertically overlap a portion of the first lower semiconductor device 121 and may be attached to the heat dissipation pad structure 171. The heat dissipation plate 185 may be spaced apart from the upper semiconductor devices 181 in a lateral direction (e.g., an X direction) and may overlap the upper semiconductor devices 181 in a lateral direction (e.g., an X direction). As the heat dissipation plate 185 and each upper semiconductor device 181 are spaced apart in the lateral direction, a gap 201 may be formed between the heat dissipation plate 185 and each upper semiconductor device 181. The gap 201 may be understood as an empty space formed by separating the heat dissipation plate 185 and each upper semiconductor device 181.

According to embodiments, components attached to the lower package LP1 (i.e., the heat dissipation plate 185 and the upper semiconductor devices 181) may be spaced apart from each other with a space therebetween. The space between the components may relieve stress generated in the semiconductor package 10 and block crack propagation.

In embodiments, the heat dissipation plate 185 is rectangular when viewed in a plan view, and may face each of four upper semiconductor devices 181 provided in the semiconductor package 10 in a lateral direction (e.g., an X direction). In embodiments, when viewed in a plan view (see, e.g., FIG. 2), the entire heat dissipation plate 185 may be positioned within a footprint of the first lower semiconductor device 121 or within the first region R1 of the first redistribution structure 110. The heat dissipation plate 185 may be thermally coupled to the first lower semiconductor device 121 through the heat dissipation pad structure 171. Heat generated in the first lower semiconductor device 121 may be dissipated to the outside through the heat dissipation pad structure 171 and the heat dissipation plate 185. Heat dissipation plate 185 may include a heat sink, heat pipe, and/or heat slug.

The heat dissipation plate 185 may include a thermally conductive material having high thermal conductivity. Thermal conductivity of a material constituting the heat dissipation plate 185 may be greater than thermal conductivity of silicon. In other words, the thermal resistance of the material constituting the heat dissipation plate 185 may be smaller than that of silicon. For example, the heat dissipation plate 185 may include a metal such as copper (Cu) or aluminum (Al) or a carbon-containing material such as graphene, graphite, and/or carbon nanotubes. The heat dissipation plate 185 may be a single piece.

The heat dissipation plate 185 may be attached to the first lower semiconductor device 121 or the heat dissipation pad structure 171 through the thermally conductive adhesive layer 187. The thermally conductive adhesive layer 187 may include a material that is thermally conductive and electrically insulative. The planar area and planar shape of the thermally conductive adhesive layer 187 may be the same as those of the heat dissipation plate 185, respectively. The thermally conductive adhesive layer 187 may include a thermal interface material, a polymer including metal powder, thermal grease, or a combination thereof.

In embodiments, the amount of heat generated by the first lower semiconductor device 121 may be greater than the amount of heat generated by the upper semiconductor devices 181. In embodiments, the first lower semiconductor device 121 may include a logic chip and/or an SoC, and the plurality of upper semiconductor devices 181 may include memory chips. In embodiments, at least one of the memory chips included in the plurality of upper semiconductor devices 181 may be used as a cache memory. According to embodiments, since the first lower semiconductor device 121 having a relatively high calorific value is thermally coupled to the heat dissipation plate 185 through the heat dissipation pad structure 171, heat dissipation characteristics of the first lower semiconductor device 121 may be improved, and it is possible to prevent performance degradation of electronic components around the first lower semiconductor device 121 due to heat generated by the first lower semiconductor device 121.

When viewed in a plan view, the heat dissipation plate 185 may be located at the center of the semiconductor package 10, and the plurality of upper semiconductor devices 181 may be symmetrically disposed with respect to the center of the semiconductor package 10. For example, the plurality of upper semiconductor devices 181 may include four upper semiconductor devices 181 arranged in a two-row and two-column structure, and the heat dissipation plate 185 may be disposed in the middle of the four upper semiconductor devices 181.

In embodiments, some of the upper semiconductor devices 181 among the plurality of upper semiconductor devices 181 may be spaced apart in a lateral direction (e.g., an X direction and/or a Y direction) with the heat dissipation plate 185 therebetween. In embodiments, when viewed in a plan view, a portion of the heat dissipation plate 185 may be disposed between two upper semiconductor devices 181 adjacent to each other in the first lateral direction (e.g., X direction) or may be disposed between two upper semiconductor devices 181 adjacent to each other in the second lateral direction (e.g., Y direction). In embodiments, when viewed in a plan view, the first segment 1851 of the heat dissipation plate 185 may be disposed between two upper semiconductor devices 181 adjacent in a first lateral direction (e.g., X direction).

Each upper semiconductor device 181 may vertically overlap a portion of the first lower semiconductor device 121. In embodiments, when viewed in a plan view, a portion of each upper semiconductor device 181 may vertically overlap the first region R1 of the first redistribution structure 110 on which the first lower semiconductor device 121 is mounted, and another portion of each upper semiconductor device 181 may vertically overlap the second region R2 of the first redistribution structure 110 in which the vertical connection conductors 155 are disposed.

The plurality of upper semiconductor devices 181 may each vertically overlap a different region of the first lower semiconductor device 121. In embodiments, the first lower semiconductor device 121 may include first overlapping regions vertically overlapping the plurality of upper semiconductor devices 181 and a second overlapping region vertically overlapping the heat dissipation plate 185. In this case, the first overlapping regions of the first lower semiconductor device 121 may be spaced apart from each other. In embodiments, in the first lower semiconductor device 121, the first overlapping regions may have the same planar area as each other.

In embodiments, each of the plurality of upper semiconductor devices 181 may vertically overlap a corresponding vertex VP among the vertices VP of the first lower semiconductor device 121. In embodiments, the upper surface 129 of the first lower semiconductor device 121 may include four vertices VP, and the plurality of upper semiconductor devices 181 may include four upper semiconductor devices 181 vertically overlapping the four vertices VP of the upper surface 129 of the first lower semiconductor device 121, respectively. For example, the vertices VP of the first lower semiconductor device 121 may correspond to the four upper corners of the first lower semiconductor device 121.

In embodiments, when viewed in cross section of the semiconductor package 10, the first lower semiconductor device 121 may vertically overlap two upper semiconductor devices 181 spaced apart in a first lateral direction (e.g., X direction) with the heat dissipation plate 185 therebetween. At this time, the ratio (i.e., L2/L1) of the length L2 along the first lateral direction (e.g., X direction) of the first overlapping region of the first lower semiconductor device 121 overlapping a single upper semiconductor device 181 to the total length L1 of the first lower semiconductor device 121 along the first lateral direction (e.g., the X direction) may be between about 20% and about 40%.

In the semiconductor package 10, a signal (e.g., data signal, control signal, power signal and/or ground signal) provided from an external device may be provided to the first lower semiconductor device 121 through a signal transmission path including the external connection terminal 141 and the first conductive redistribution pattern 113. A signal (e.g., data signal, control signal, power signal and/or ground signal) provided from an external device may be provided to the upper semiconductor device 181 through a signal transmission path including the external connection terminal 141, the first conductive redistribution pattern 113, the vertical connection conductor 155, and the second conductive redistribution pattern 163. Between the first lower semiconductor device 121 and the upper semiconductor device 181, electrical signals may be transmitted through the first conductive redistribution pattern 113, the vertical connection conductor 155, and the second conductive redistribution pattern 163.

In a typical semiconductor package, when semiconductor chips are arranged side by side along the mounting surface of the package substrate on the package substrate, the dimensions of the semiconductor package (i.e., dimensions in the horizontal direction (X direction and/or Y direction)) may be increased. In addition, when a semiconductor chip of an upper package is disposed above a semiconductor chip of a lower package, it is difficult to dissipate heat generated from the semiconductor chip of the lower package to the outside.

According to embodiments, the plurality of upper semiconductor devices 181 are arranged to vertically overlap different regions of the first lower semiconductor device 121 included in the lower package LP1, and the heat dissipation plate 185 may be attached on the first lower semiconductor device 121. Accordingly, it is possible to provide the semiconductor package 10 with improved heat dissipation characteristics while miniaturizing the footprint of the semiconductor package.

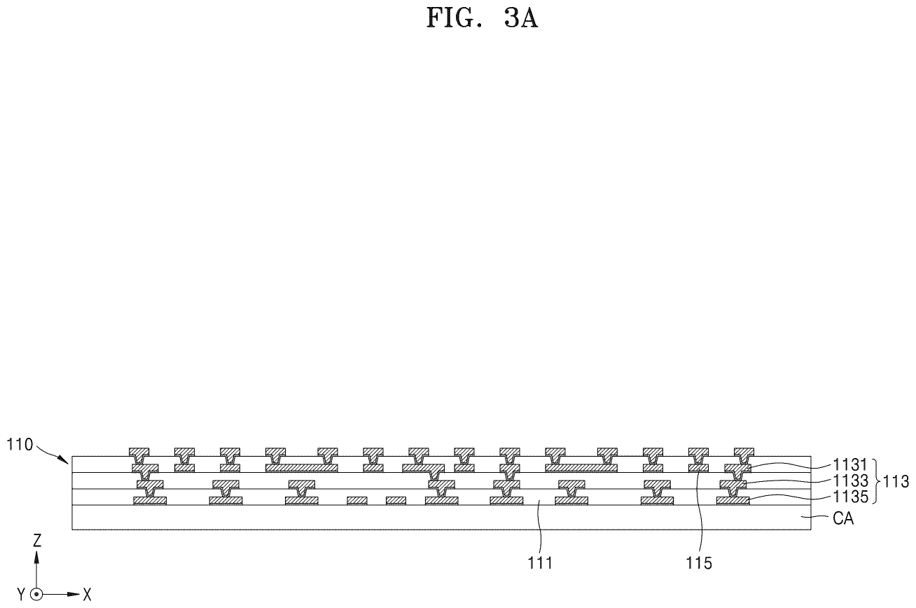

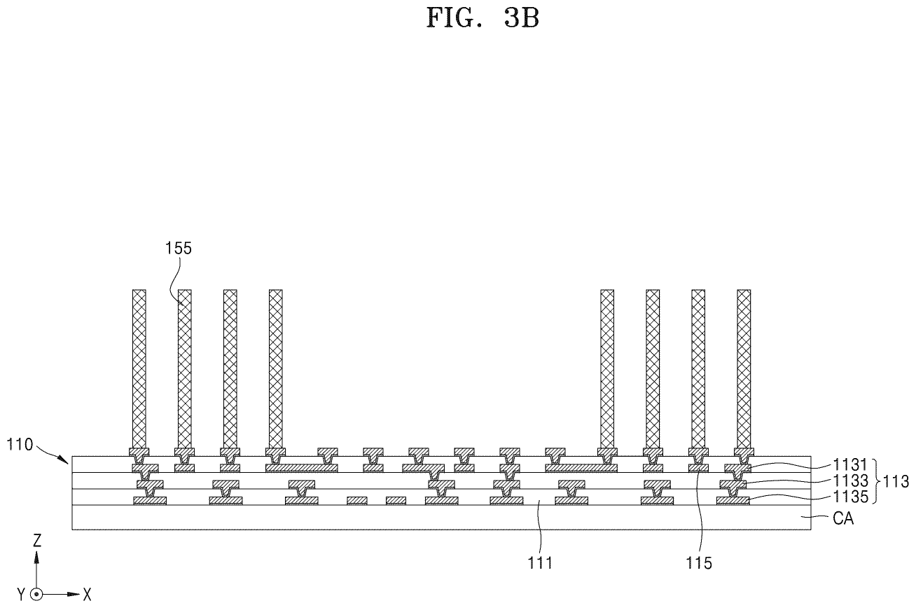

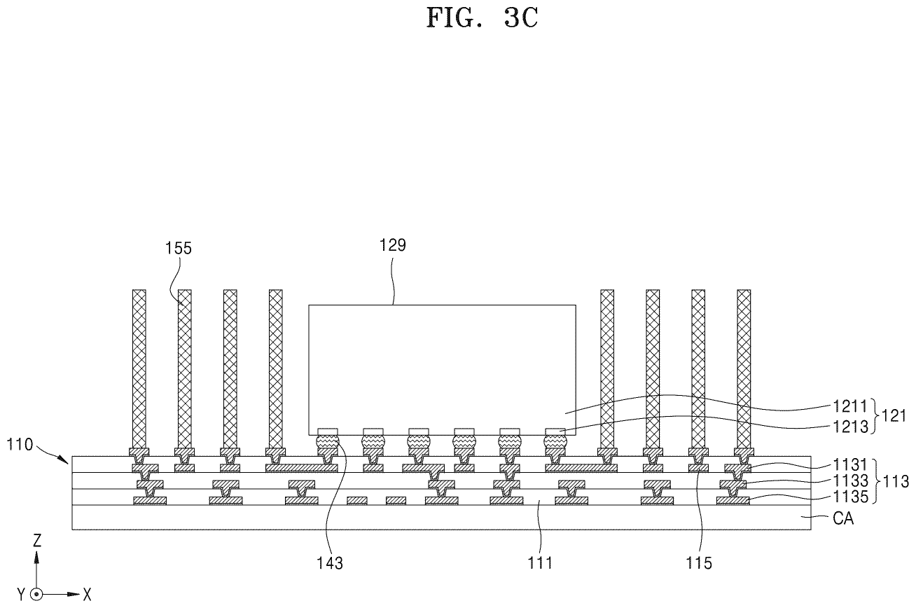

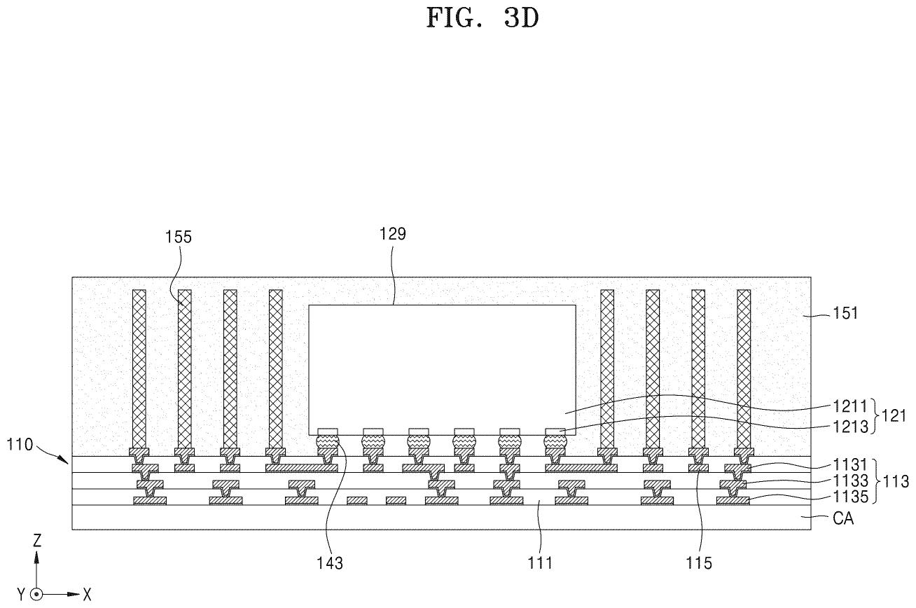

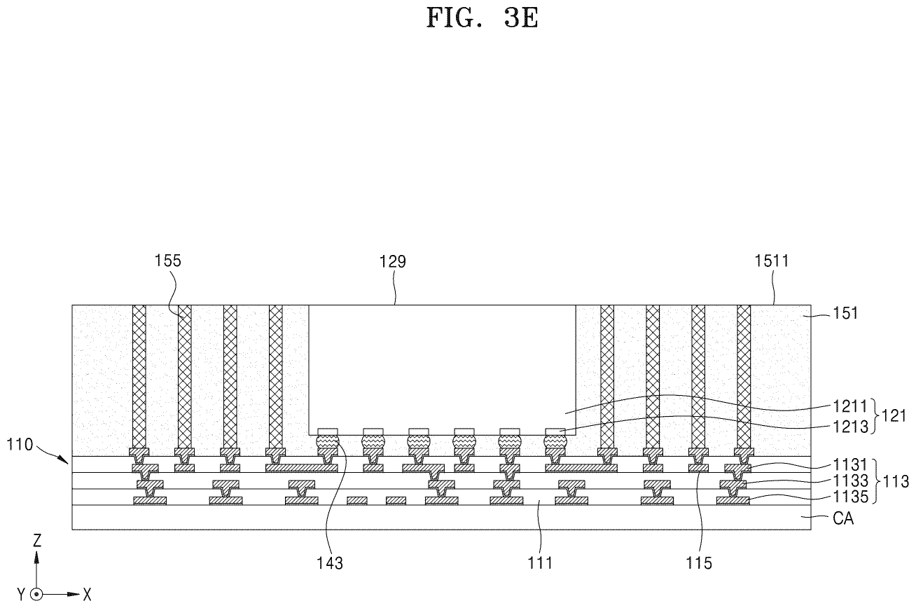

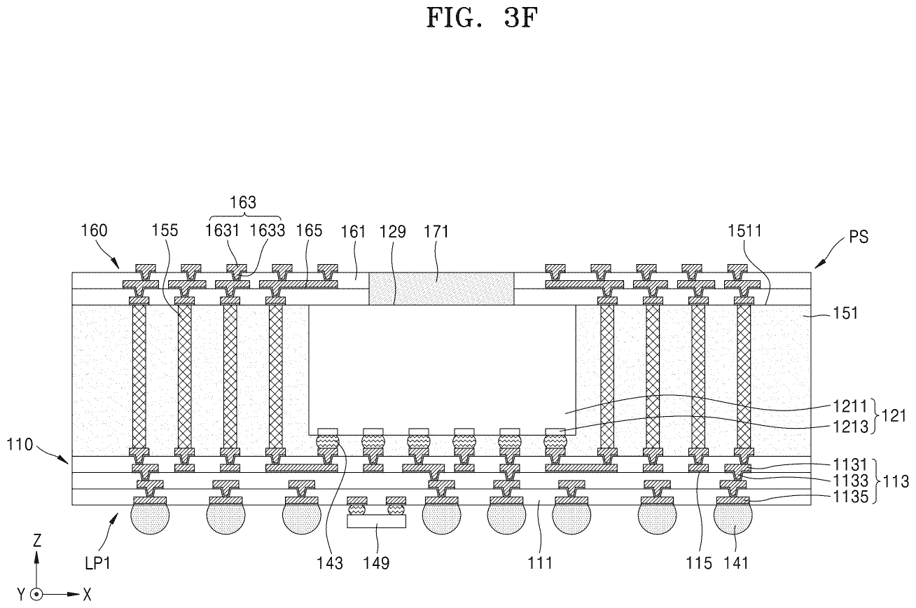

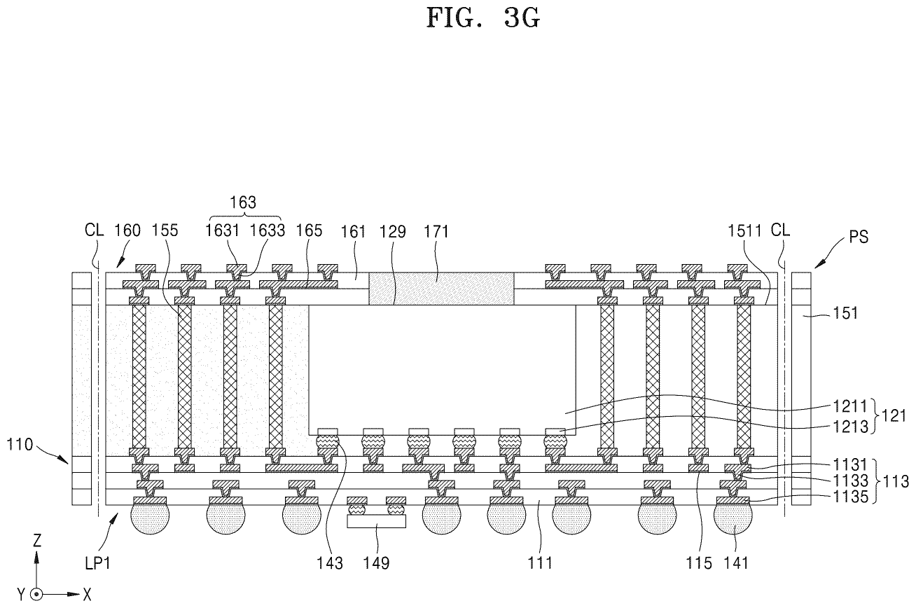

FIGS. 3A to 3G are cross-sectional views illustrating a method of manufacturing a semiconductor package 10 according to embodiments. Hereinafter, a method of manufacturing the semiconductor package 10 described with reference to FIGS. 1 and 2 will be described with reference to FIGS. 3A to 3G.

Referring to FIG. 3A, a first redistribution structure 110 is formed on the carrier substrate CA. The first redistribution structure 110 may include a plurality of first redistribution insulating layers 111 sequentially stacked on the carrier substrate CA, and a first conductive redistribution pattern 113 insulated by a plurality of first redistribution insulating layers 111. The first conductive redistribution pattern 113 may include an external connection pad 1135 extending along the upper surface of the carrier substrate CA, first conductive layers 1131 extending along upper surfaces of the plurality of first redistribution insulating layers 111, and a first conductive via pattern 1133 extending through any one of the plurality of first redistribution insulating layers 111.

To form the first redistribution structure 110, external connection pads 1135 may first be formed on the carrier substrate CA. The external connection pad 1135 may be formed through a plating process. For example, after forming the seed metal layer 115 on the carrier substrate CA, an external connection pad 1135 may be formed by performing a plating process using the seed metal layer 115. After forming the external connection pad 1135, a first step of forming an insulating film covering the external connection pad 1135 and having a via hole and a second step of forming a first conductive via pattern 1133 filling the via hole of the insulating layer and a first conductive layer 1131 extending along an upper surface of the insulating film may be performed. The second step of forming the first conductive via pattern 1133 and the first conductive layer 1131 may include a plating process using the seed metal layer 115. Thereafter, the first redistribution structure 110 having a multi-layer interconnect structure may be formed by repeating the first step of forming the insulating film and the second step of forming the first conductive layer 1131 and the first conductive via pattern 1133 several times.

Referring to FIG. 3B, vertical connection conductors 155 are formed on the first redistribution structure 110. The vertical connection conductors 155 may be formed using a plating process.

Referring to FIG. 3C, the first lower semiconductor device 121 is mounted on the first redistribution structure 110. The first lower semiconductor device 121 may be mounted on the first redistribution structure 110 through the first chip connection bumps 143.

Referring to FIG. 3D, a molding layer 151 covering the first lower semiconductor device 121 and the vertical connection conductors 155 is formed on the first redistribution structure 110. To form the molding layer 151, a molding material may be supplied on the carrier substrate CA, and then the molding material may be cured.

Referring to FIG. 3E, a portion of the molding layer 151 may be removed to expose the first lower semiconductor device 121 and the vertical connection conductors 155. To remove a portion of the molding layer 151, a chemical mechanical polishing (CMP) process, a grinding process, or the like may be performed from the upper side of the structure shown in FIG. 3D. For example, a portion of the molding layer 151, a portion of each of the vertical connection conductors 155, and a portion of the first lower semiconductor device 121 may be removed through a polishing process. In embodiments, as a result of the polishing process, the polished upper surface 1511 of the molding layer 151 may be coplanar with the upper surface 129 of the first lower semiconductor device 121 and the upper surface of each of the vertical connection conductors 155.

Referring to FIG. 3F, a second redistribution structure 160 is formed on the upper surface 1511 of the molding layer 151 and the upper surface 129 of the first lower semiconductor device 121. The second redistribution structure 160 may include a plurality of second redistribution insulating layers 161 sequentially stacked on the upper surface 1511 of the molding layer 151 and the upper surface 129 of the first lower semiconductor device 121 and a second conductive redistribution pattern 163 insulated by a plurality of second redistribution insulating layers 161. The second conductive redistribution pattern 163 may include second conductive layers 1631 extending along upper surfaces of the plurality of second redistribution insulating layers 161 and a second conductive via pattern 1633 extending through any one of the plurality of second redistribution insulating layers 161.

To form the second redistribution structure 160, first, the lowermost second conductive layer 1631 connected to the vertical connection conductors 155 may be formed. For example, after forming the seed metal layer 165 on the vertical connection conductors 155, a plating process using the seed metal layer 165 may be performed to form the lowermost second conductive layer 1631. Next, a first step of forming an insulating film covering the lowermost second conductive layer 1631 and having a via hole and a second step of forming a second conductive via pattern 1633 filling the via hole of the insulating film and a second conductive layer 1631 extending along an upper surface of the insulating film may be performed. The second step of forming the second conductive via pattern 1633 and the second conductive layer 1631 may include a plating process using the seed metal layer 165. Thereafter, a second redistribution structure 160 having a multi-layer interconnect structure may be formed by repeating the first step of forming the insulating film and the second step of forming the second conductive layer 1631 and the second conductive via pattern 1633 several times.

After forming the second redistribution structure 160, a through hole is formed in the second redistribution insulating layer 161, and a heat dissipation pad structure 171 is formed in the through hole of the second redistribution insulating layer 161. For example, to form the heat dissipation pad structure 171, a through hole partially exposing the upper surface 129 of the first lower semiconductor device 121 may be formed in the second redistribution insulating layer 161, and the through hole may be filled with a conductive material.

The first redistribution structure 110, the first lower semiconductor device 121, the vertical connection conductors 155, the molding layer 151, the second redistribution structure 160, and the heat dissipation pad structure 171 may form a package structure PS in the form of a panel.

Thereafter, the carrier substrate CA is removed from the first redistribution structure 110, and external connection terminals 141 and passive components 149 are attached to the lower side of the first redistribution structure 110.

Referring to FIG. 3G, the package structure PS may be cut along the cutting line CL. Through a process of cutting the package structure PS, the package structure PS may be separated into a plurality of lower packages LP1.

Next, referring to FIG. 1, a plurality of upper packages UP and a heat dissipation plate 185 are attached to the lower package LP1 separated into individual units. Each upper semiconductor device 181 may be mounted on the second redistribution structure 160 to vertically overlap a portion of the first lower semiconductor device 121, and the heat dissipation plate 185 may be attached on the heat dissipation pad structure 171 through the thermally conductive adhesive layer 187.

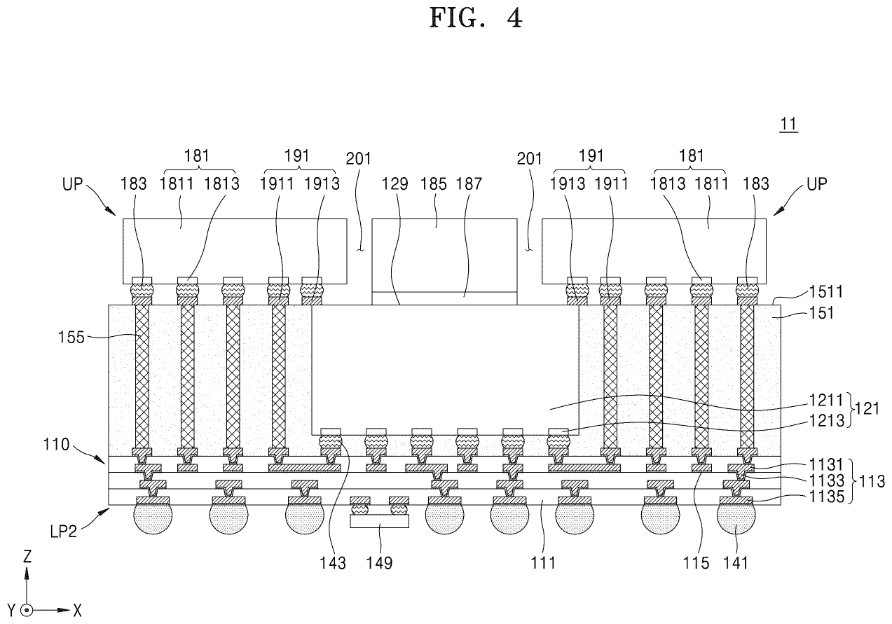

FIG. 4 is a cross-sectional view of a semiconductor package 11 according to embodiments. Hereinafter, the semiconductor package 11 shown in FIG. 4 will be described, focusing on differences from the semiconductor package 10 described with reference to FIGS. 1 and 2.

Referring to FIG. 4, the lower package LP2 of the semiconductor package 11 may include the conductive layer 191 provided on the upper surface 1511 of the molding layer 151. The conductive layer 191 may include conductive pads 1911 connected to upper surfaces of the vertical connection conductors 155 and one or more dummy pads 1913 not connected to the vertical connection conductors 155. One or more dummy pads 1913 may be disposed on the upper surface 1511 of the molding layer 151 and/or the upper surface 129 of the first lower semiconductor device 121. A material of the conductive layer 191 may be substantially the same as or similar to that of the first conductive layer 1131. Each upper semiconductor device 181 may be disposed on the conductive pads 1911 and one or more dummy pads 1913 of the conductive layer 191 through connection terminals 183. Each upper semiconductor device 181 may be electrically and physically connected to the vertical connection conductors 155 through the conductive pads 1911 of the conductive layer 191. Also, in the semiconductor package 11, the heat dissipation plate 185 may be attached to the upper surface 129 of the first lower semiconductor device 121 by a thermally conductive adhesive layer 187.

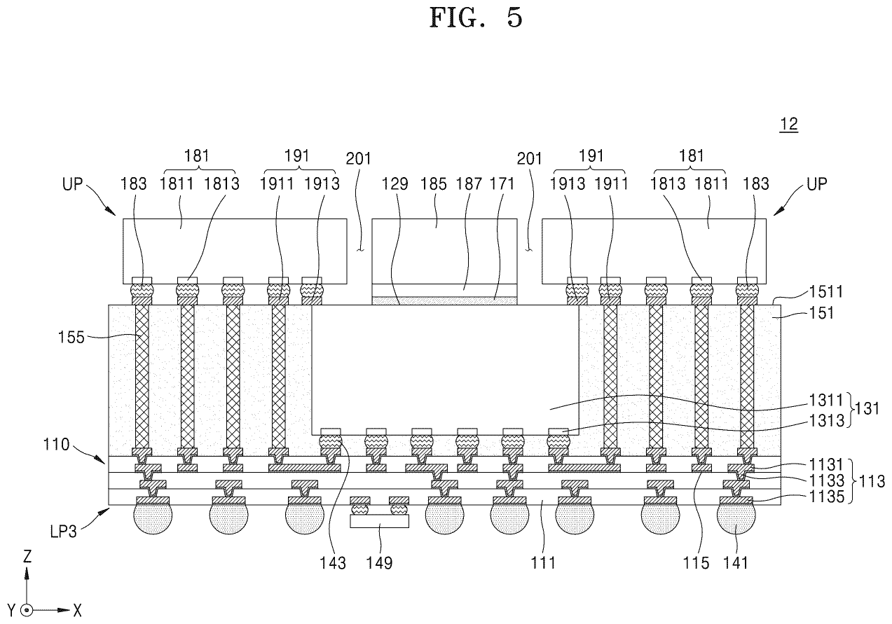

FIG. 5 is a cross-sectional view of a semiconductor package 12 according to embodiments. Hereinafter, the semiconductor package 12 shown in FIG. 5 will be described, focusing on differences from the semiconductor package 11 described with reference to FIG. 4.

Referring to FIG. 5, in the lower package LP3 of the semiconductor package 12, a heat dissipation pad structure 171 may be disposed on the upper surface 129 of the first lower semiconductor device 121. A heat dissipation plate 185 may be attached to the heat dissipation pad structure 171. The heat dissipation pad structure 171 may have a plate shape partially covering the upper surface 129 of the first lower semiconductor device 121. The heat dissipation pad structure 171 may be formed through the same metal interconnect process as the conductive layer 191. A thickness of the heat dissipation pad structure 171 may be substantially the same as that of the conductive layer 191. A material of the heat dissipation pad structure 171 may be substantially the same as that of the conductive layer 191.

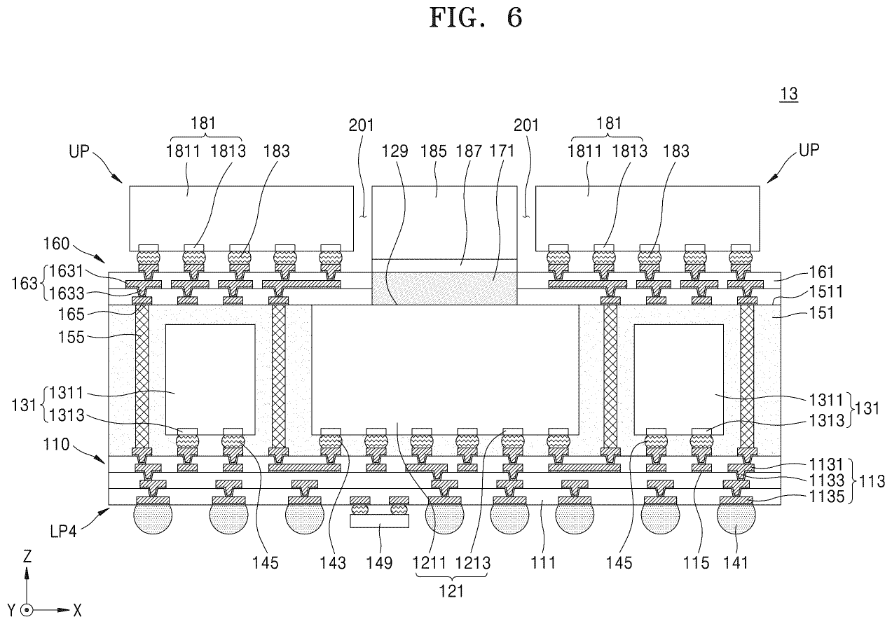

FIG. 6 is a cross-sectional view of a semiconductor package 13 according to embodiments. Hereinafter, the semiconductor package 13 shown in FIG. 6 will be described, focusing on differences from the semiconductor package 10 described with reference to FIGS. 1 and 2.

Referring to FIG. 6, in the semiconductor package 13, the lower package LP4 may further include the second lower semiconductor device 131 mounted on the second region R2 of FIG. 2 of the first redistribution structure 110. In embodiments, the second lower semiconductor device 131 may include any one of a memory chip, a logic chip, an SoC, a PMIC chip, and an RFIC chip.

The second lower semiconductor device 131 may include a semiconductor substrate 1311 and chip pads 1313. The second lower semiconductor device 131 may be mounted on the first redistribution structure 110 in a flip chip method. In this case, the lower surface of the semiconductor substrate 1311 may be an active surface of the semiconductor substrate 1311, and the upper surface of the semiconductor substrate 1311 may be an inactive surface of the semiconductor substrate 1311. A semiconductor element layer of the second lower semiconductor device 131 may be disposed on a lower surface of the semiconductor substrate 1311, and chip pads 1313 may be provided on a lower surface of the second lower semiconductor device 131. Second chip connection bumps 145 configured to electrically connect the chip pads 1313 of the second lower semiconductor device 131 to the first conductive redistribution pattern 113 may be disposed between each of the chip pads 1313 of the second lower semiconductor device 131 and a corresponding portion of the first redistribution structure 110. The second lower semiconductor device 131 may be spaced apart from the first lower semiconductor device 121 in a lateral direction (e.g., an X direction), and may vertically overlap at least one of the upper semiconductor devices 181. The second lower semiconductor device 131 may be electrically connected to the first lower semiconductor device 121 through the first conductive redistribution pattern 113. The second lower semiconductor device 131 may be electrically connected to the upper semiconductor device 181 through the first conductive redistribution pattern 113, the vertical connection conductors 155, and the second conductive redistribution pattern 163.

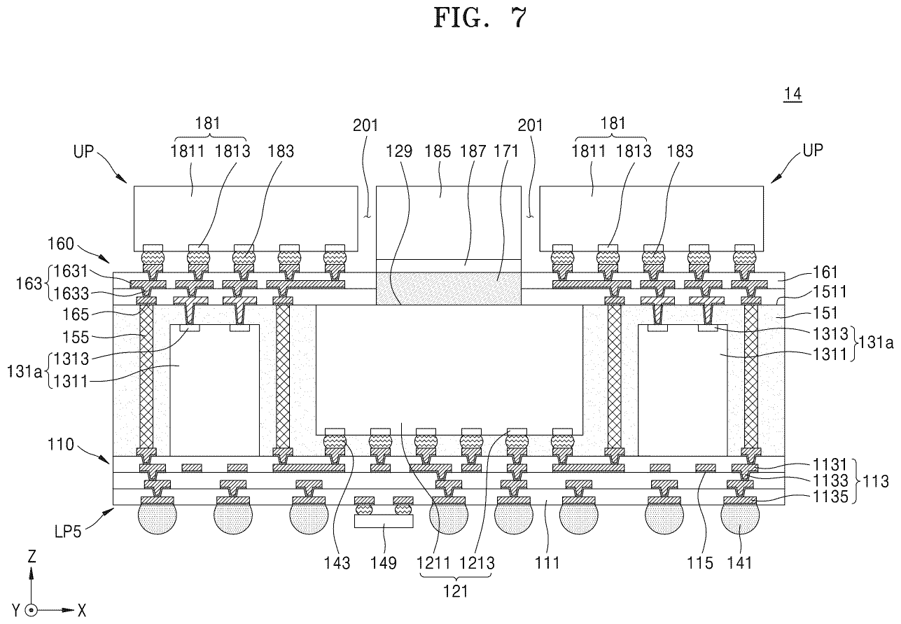

FIG. 7 is a cross-sectional view of a semiconductor package 14 according to embodiments. Hereinafter, the semiconductor package 14 shown in FIG. 7 will be described, focusing on differences from the semiconductor package 13 described with reference to FIG. 6.

Referring to FIG. 7, in the lower package LP5 of the semiconductor package 14, the second lower semiconductor device 131a may be mounted on the first redistribution structure 110 in a face-up manner. A lower surface of the semiconductor substrate 1311 may be an inactive surface of the semiconductor substrate 1311, and an upper surface of the semiconductor substrate 1311 may be an active surface of the semiconductor substrate 1311. A semiconductor element layer of the second lower semiconductor device 131a may be disposed on an upper surface of the semiconductor substrate 1311, and a chip pad 1313 may be provided in an upper surface of the second lower semiconductor device 131a. In the second redistribution structure 160, some of the plurality of second conductive via patterns 1633 may pass through the molding layer 151 and be connected to the chip pads 1313 of the second lower semiconductor device 131a. The second lower semiconductor device 131a may be electrically connected to the upper semiconductor device 181 through the second conductive redistribution pattern 163.

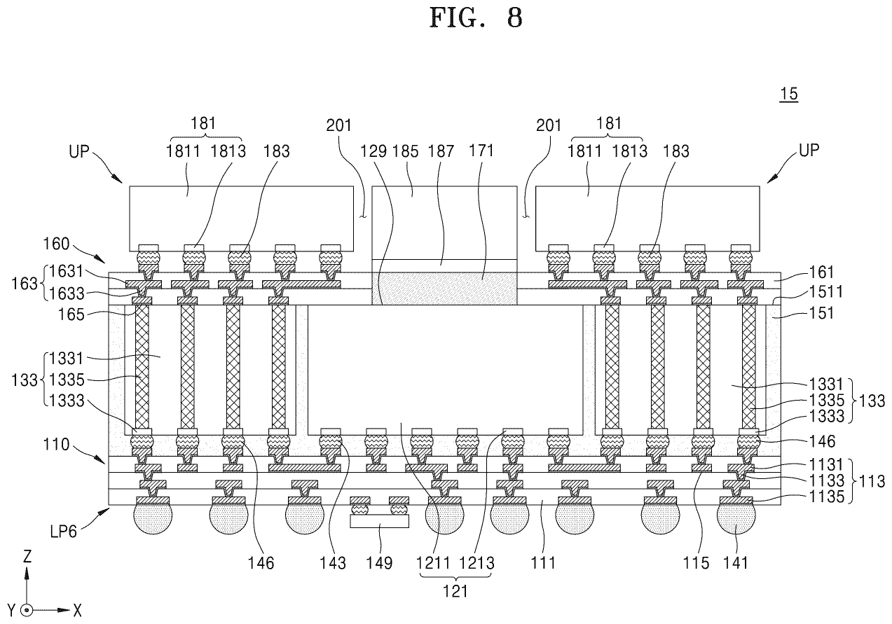

FIG. 8 is a cross-sectional view of a semiconductor package 15 according to embodiments. Hereinafter, the semiconductor package 15 shown in FIG. 8 will be described, focusing on differences from the semiconductor package 10 described with reference to FIGS. 1 and 2.

Referring to FIG. 8, in the semiconductor package 15, the lower package LP6 may further include a dummy chip 133 mounted on the second region R2 of FIG. 2 of the first redistribution structure 110. The dummy chip 133 may be mounted on the first redistribution structure 110 through the dummy connection bumps 146. The dummy chip 133 may include a dummy semiconductor substrate 1331, dummy connection pads 1333 provided on the lower surface of the dummy semiconductor substrate 1331 and connected to the dummy connection bumps 146, and vertical connection conductors 1335 extending through the dummy semiconductor substrate 1331. The dummy chip 133 provides an electrical signal path extending in a vertical direction (e.g., Z direction) from the semiconductor package 15, but does not include individual elements such as transistors. The first lower semiconductor device 121 may be electrically connected to each upper semiconductor device 181 through a signal transmission path including the first conductive redistribution pattern 113, dummy connection bumps 146, dummy connection pads 1333, vertical connection conductors 1335, and the second conductive redistribution pattern 163.

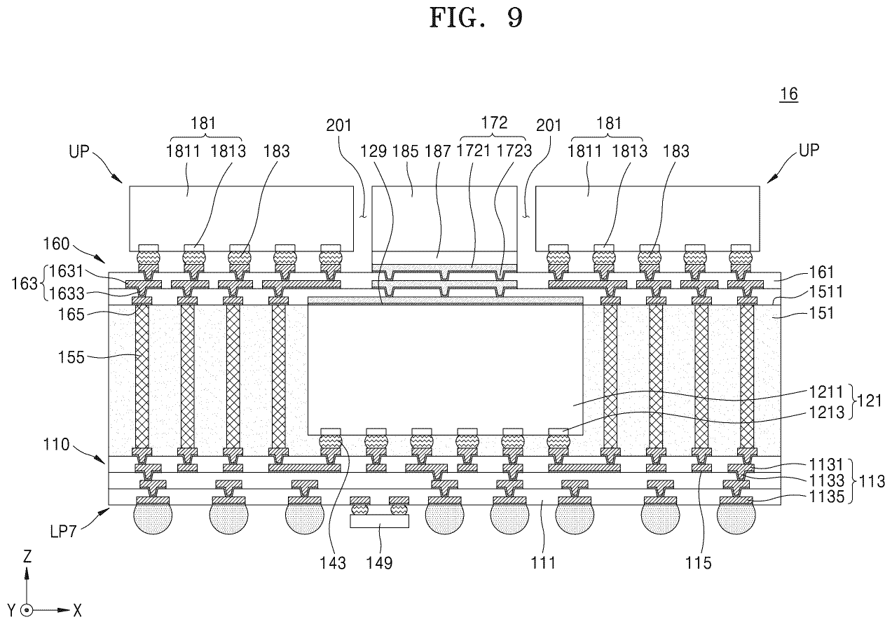

FIG. 9 is a cross-sectional view of a semiconductor package 16 according to embodiments. Hereinafter, the semiconductor package 16 shown in FIG. 9 will be described, focusing on differences from the semiconductor package 10 described with reference to FIGS. 1 and 2.

Referring to FIG. 9, in the lower package LP7 of the semiconductor package 16, a heat dissipation pad structure 172 may include heat dissipation pad layers 1721 and heat dissipation via patterns 1723.

The heat dissipation pad layers 1721 may be disposed at different vertical levels to form a multilayer structure. Each of the heat dissipation pad layers 1721 may have a plate shape extending substantially parallel to the upper surface 129 of the first lower semiconductor device 121. Each of the heat dissipation pad layers 1721 may be positioned at the same vertical level as any one of the second conductive layers 1631. Each of the heat dissipation pad layers 1721 may have the same or similar thickness as the corresponding second conductive layer 1631 positioned at the same vertical level. Among the heat dissipation pad layers 1721, the lowermost heat dissipation pad layer 1721 may extend along the upper surface 129 of the first lower semiconductor device 121 and contact the upper surface 129 of the first lower semiconductor device 121. In embodiments, the lowermost heat dissipation pad layer 1721 of the heat dissipation pad layers 1721 may entirely cover the upper surface 129 of the first lower semiconductor device 121. The heat dissipation via patterns 1723 may extend in a vertical direction (e.g., a Z direction) through at least one of the plurality of second redistribution insulating layers 161. The heat dissipation via patterns 1723 may connect heat dissipation pad layers 1721 disposed at different vertical levels. A seed metal layer 165 may be disposed on surfaces of the heat dissipation pad layer 1721 and the heat dissipation via patterns 1723. For example, the seed metal layer 165 may extend along the bottom surface of the heat dissipation pad layer 1721 and/or may extend along sidewalls and bottom surfaces of the heat dissipation via pattern 1723. In embodiments, the heat dissipation pad structure 172 may be formed together with the second conductive redistribution pattern 163 of the second redistribution structure 160 through the same metal interconnect process. In this case, the material and/or material composition of the heat dissipation pad structure 172 may be substantially the same as the material and/or material composition of the second conductive redistribution pattern 163.

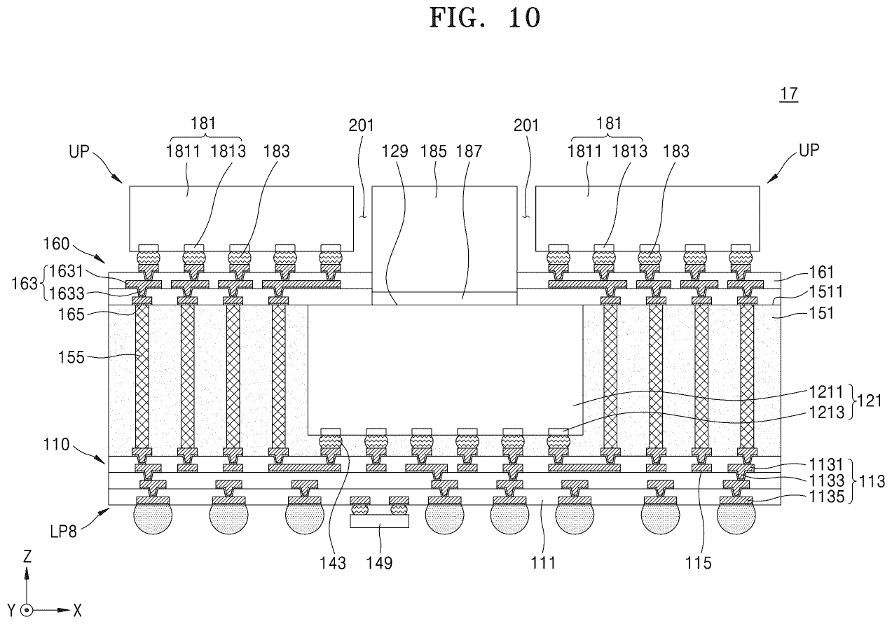

FIG. 10 is a cross-sectional view of a semiconductor package 17 according to embodiments. Hereinafter, the semiconductor package 17 shown in FIG. 10 will be described, focusing on differences from the semiconductor package 10 described with reference to FIGS. 1 and 2.

Referring to FIG. 10, in the lower package LP8 of the semiconductor package 17, the second redistribution structure 160 may include a through hole penetrating the second redistribution insulating layer 161, and the heat dissipation plate 185 may be accommodated in the through hole of the second redistribution insulating layer 161. The heat dissipation plate 185 may be attached to a portion of the upper surface 129 of the first lower semiconductor device 121 overlapping the through hole of the second redistribution insulating layer 161 through the thermally conductive adhesive layer 187.

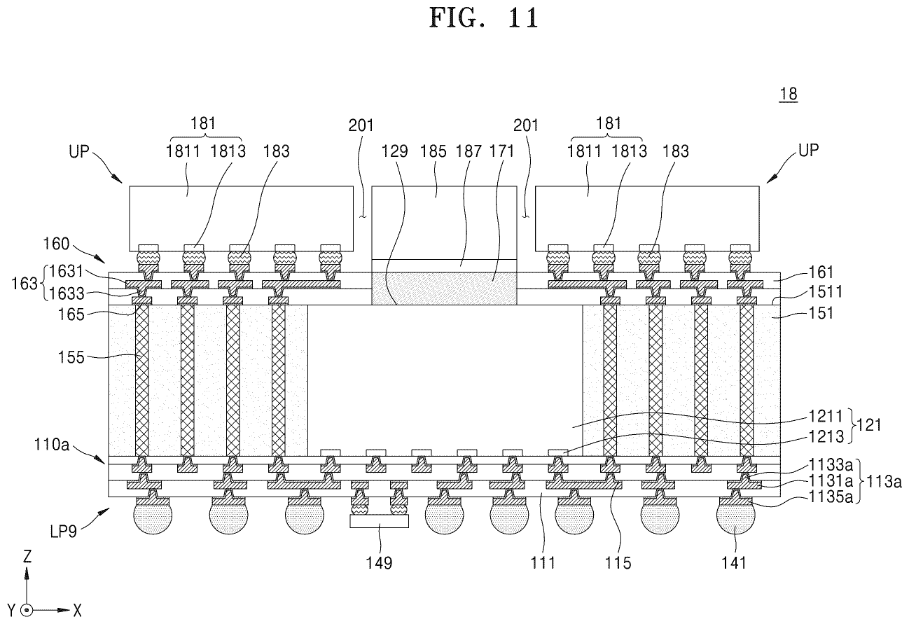

FIG. 11 is a cross-sectional view of a semiconductor package 18 according to embodiments. Hereinafter, the semiconductor package 18 shown in FIG. 11 will be described, focusing on differences from the semiconductor package 10 described with reference to FIGS. 1 and 2.

Referring to FIG. 11, in the lower package LP9 of the semiconductor package 18, the first lower semiconductor device 121 may be directly connected to the first redistribution structure 110a.

The first conductive redistribution pattern 113a of the first redistribution structure 110a may include first conductive layers 1131a, first conductive via patterns 1133a, and external connection pads 1135a. The first conductive layers 1131a may include line patterns extending along the lower surfaces of each of the plurality of first redistribution insulating layers 111. The first conductive via patterns 1133a may electrically connect first conductive layers 1131a disposed at different vertical levels to each other, or may electrically connect the first conductive layer 1131a to the lower connection pads 1213 of the first lower semiconductor device 121. The external connection pad 1135a may protrude downward from the lower surface of the lowermost insulating layer among the plurality of first redistribution insulating layers 111. The external connection pad 1135a may include a portion extending along the lower surface of the lowermost insulating layer among the plurality of first redistribution insulating layers 111 and a portion extending through the lowermost insulating layer. In embodiments, each of the plurality of first conductive via patterns 1133a may have a tapered shape in which a horizontal width narrows from a lower side toward an upper side thereof. In other words, the horizontal width of each of the plurality of first conductive via patterns 1133a may gradually decrease as it is closer to the lower connection pad 1213 of the first lower semiconductor device 121.

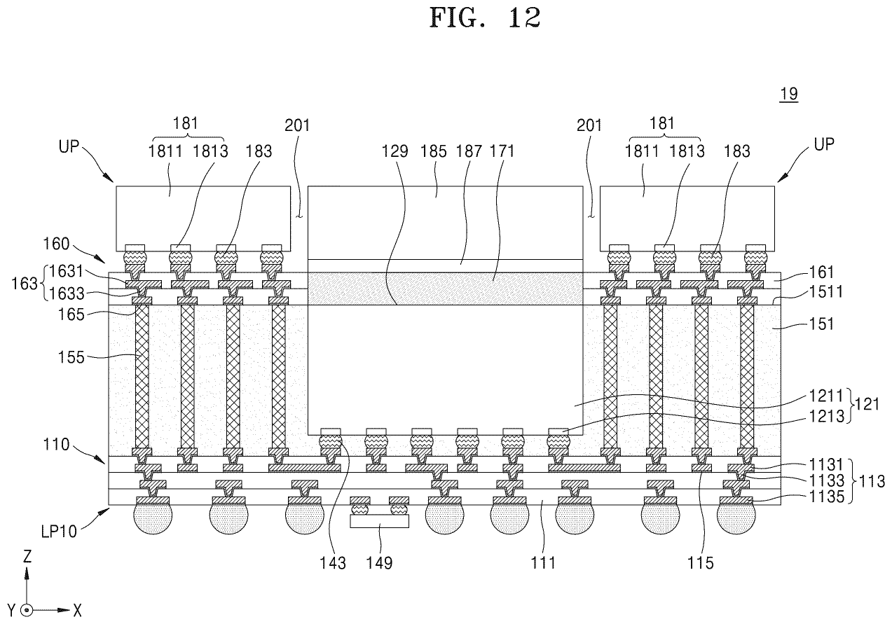

FIG. 12 is a cross-sectional view of a semiconductor package 19 according to embodiments. Hereinafter, the semiconductor package 19 shown in FIG. 12 will be described, focusing on differences from the semiconductor package 10 described with reference to FIGS. 1 and 2.

Referring to FIG. 12, in the semiconductor package 19, the upper semiconductor device 181 may not vertically overlap the first lower semiconductor device 121. For example, when viewed in a plan view, the first lower semiconductor device 121 may be in the first region R1 of FIG. 2 of the first redistribution structure 110, and the upper semiconductor device 181 may be outside the first region R1 of the first redistribution structure 110. In the lower package LP10, the heat dissipation pad structure 171 may extend along the entire upper surface 129 of the first lower semiconductor device 121 and may entirely cover the upper surface 129 of the first lower semiconductor device 121.

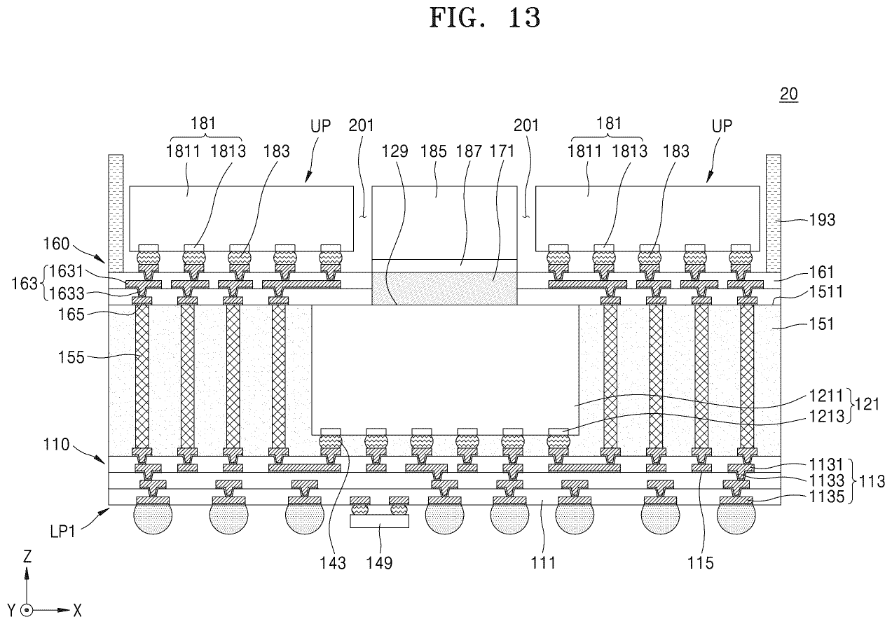

FIG. 13 is a cross-sectional view of a semiconductor package 20 according to embodiments. Hereinafter, the semiconductor package 20 shown in FIG. 13 will be described, focusing on differences from the semiconductor package 10 described with reference to FIGS. 1 and 2.

Referring to FIG. 13, the semiconductor package 20 may include a stiffener 193 disposed on the lower package LP1. The stiffener 193 may be disposed on the lower package LP1 to overlap the upper semiconductor device 181 and the heat dissipation plate 185 in a lateral direction (e.g., X direction and/or Y direction). The stiffener 193 may improve mechanical stability of the semiconductor package 20 by mechanically supporting the lower package LP1. For example, as the stiffener 193 mechanically supports the lower package LP1, the stiffener 193 may be configured to alleviate and suppress warpage generated due to differences in thermal expansion coefficients of individual components constituting the semiconductor package 20. The stiffener 193 may include a metal such as steel or copper (Cu). The stiffener 193 may be attached on the second redistribution structure 160 or the molding layer 151.

For example, the stiffener 193 may be attached on the second redistribution structure 160 through an adhesive material layer. The stiffener 193 may be disposed on the edge region of the second redistribution structure 160. The stiffener 193 may have a ring shape extending along the circumference of the upper surface of the second redistribution structure 160. The stiffener 193 may consist of a single stiffener block or multiple stiffener blocks spaced apart from each other.

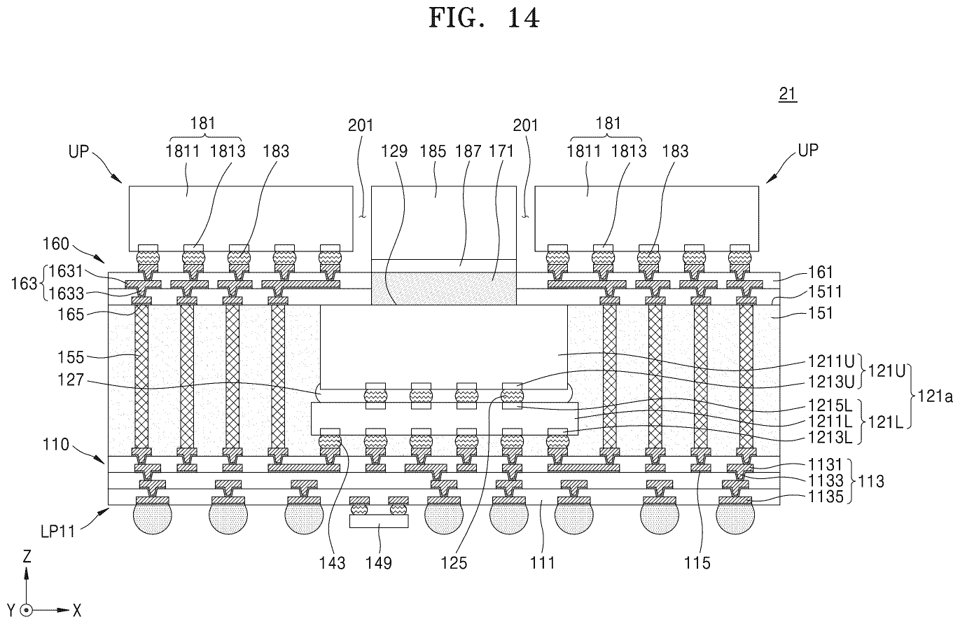

FIG. 14 is a cross-sectional view of a semiconductor package 21 according to embodiments. Hereinafter, the semiconductor package 21 shown in FIG. 14 will be described, focusing on differences from the semiconductor package 10 described with reference to FIGS. 1 and 2.

Referring to FIG. 14, in the lower package LP11 of the semiconductor package 21, the first lower semiconductor device 121a may include a plurality of vertically stacked semiconductor chips. For example, the first lower semiconductor device 121a may include a lower semiconductor chip 121L and an upper semiconductor chip 121U stacked on the lower semiconductor chip 121L. The lower semiconductor chip 121L may include a lower semiconductor substrate 1211L, lower connection pads 1213L provided on the lower side of the lower semiconductor substrate 1211L and contacting the first chip connection bumps 143, and upper connection pads 1215L provided on the upper side of the lower semiconductor substrate 1211L. The lower semiconductor chip 121L may further include through electrodes that penetrate the lower semiconductor substrate 1211L and electrically connect the lower connection pads 1213L to the upper connection pads 1215L. The upper semiconductor chip 121U may include an upper semiconductor substrate 1211U and lower connection pads 1213U provided below the upper semiconductor substrate 1211U. The upper connection pads 1215L of the lower semiconductor chip 121L may be electrically and physically connected to the lower connection pads 1213U of the upper semiconductor chip 121U through inter-chip connection bumps 125. A gap-fill insulating layer 127 may be disposed between the lower semiconductor chip 121L and the upper semiconductor chip 121U to surround sidewalls of the inter-chip connection bumps 125. The gap-fill insulating layer 127 may be formed from, for example, a non-conductive film (NCF).

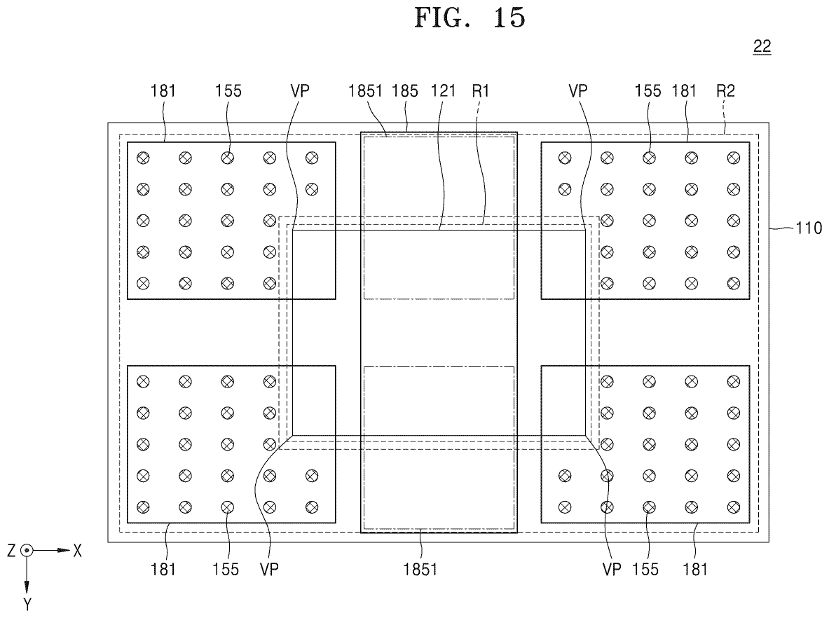

FIG. 15 is a layout diagram showing a main configuration of a semiconductor package 22 according to embodiments. Hereinafter, the semiconductor package 22 shown in FIG. 15 will be described, focusing on differences from the semiconductor package 10 described with reference to FIGS. 1 and 2.

Referring to FIG. 15, in the semiconductor package 22, a part of the heat dissipation plate 185 may be located in (e.g., inside a footprint of) the first lower semiconductor device 121, and another part of the heat dissipation plate 185 may protrude from (e.g., may be located outside a footprint of) the first lower semiconductor device 121 in a lateral direction (e.g., X direction and/or Y direction). When viewed in a plan view, a part of the heat dissipation plate 185 may be located in the first region R1 of the first redistribution structure 110, and another part of the heat dissipation plate 185 may be located outside the first region R1 of the first redistribution structure 110.

In embodiments, the heat dissipation plate 185 may extend from one edge of the upper surface of the lower package LP1 (see FIG. 1) to the other edge in the second lateral direction (e.g., Y direction). As the heat dissipation plate 185 extends from one edge to the other edge of the upper surface of the lower package (LP1 in FIG. 1) in the second lateral direction (e.g., Y direction), two upper semiconductor devices 181 adjacent to each other in the first lateral direction (e.g., X direction) may not directly face each other. Instead, the two adjacent upper semiconductor devices 181 may each face a different side of the heat dissipation plate 185.

When viewed in a plan view, a part of the heat dissipation plate 185 may be located in the first region R1 of the first redistribution structure 110, and another part of the heat dissipation plate 185 may be located outside the first region R1 of the first redistribution structure 110. In other words, a part of the first segment 1851 of the heat dissipation plate 185 may vertically overlap the first lower semiconductor device 121, and another part of the first segment 1851 of the heat dissipation plate 185 may not vertically overlap the first lower semiconductor device 121.

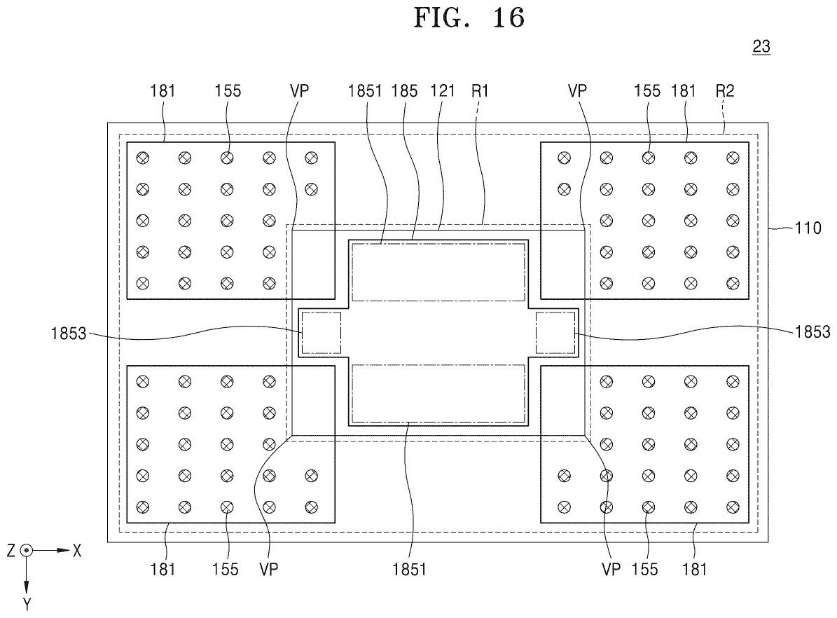

FIG. 16 is a layout diagram showing a main configuration of a semiconductor package 23 according to embodiments. Hereinafter, the semiconductor package 23 shown in FIG. 16 will be described, focusing on differences from the semiconductor package 10 described with reference to FIGS. 1 and 2.

Referring to FIG. 16, the heat dissipation plate 185 may include a first segment 1851 disposed between two upper semiconductor devices 181 that are adjacent to each other in a first lateral direction (e.g., X direction) and a second segment 1853 between two upper semiconductor devices 181 that are adjacent to each other in the second lateral direction (e.g., Y direction). The heat dissipation plate 185 may have a cross shape when viewed in a plan view.

In embodiments, when viewed in a plan view, the entire heat dissipation plate 185 may be positioned within a footprint of the first lower semiconductor device 121 or within the first region R1 of the first redistribution structure 110. In embodiments, although not shown in the drawings, when viewed in a plan view, a part of the first segment 1851 of the heat dissipation plate 185 may be located in the first region R1 of the first redistribution structure 110, and another part of the first segment 1851 of the heat dissipation plate 185 may be located outside the first region R1 of the first redistribution structure 110. In embodiments, although not shown in the drawings, when viewed in a plan view, a part of the second segment 1853 of the heat dissipation plate 185 may be located in the first region R1 of the first redistribution structure 110, and another part of the second segment 1853 of the heat dissipation plate 185 may be located outside the first region R1 of the first redistribution structure 110.

While the inventive concept has been particularly shown and described with reference to embodiments thereof, it will be understood that various changes in form and details may be made therein without departing from the spirit and scope of the disclosure.

What is claimed is:

1. A semiconductor package comprising:
a first redistribution structure including a first redistribution insulating layer and a first redistribution pattern;
a first lower semiconductor device mounted on the first redistribution structure;
a molding layer surrounding the first lower semiconductor device on the first redistribution structure;
a plurality of vertical connection conductors in the molding layer, the plurality of vertical connection conductors being electrically connected to the first redistribution pattern;
a heat dissipation plate on an upper surface of the first lower semiconductor device; and
a plurality of upper semiconductor devices on the molding layer and on the first lower semiconductor device, each of the plurality of upper semiconductor devices vertically overlapping a different respective region of the first lower semiconductor device,
wherein the plurality of upper semiconductor devices are laterally spaced apart from the heat dissipation plate such that a gap is formed between each of the plurality of upper semiconductor devices and the heat dissipation plate, and
wherein each of the plurality of upper semiconductor devices vertically overlaps a corresponding vertex among vertices of the upper surface of the first lower semiconductor device.

2. The semiconductor package of claim 1, wherein the upper surface of the first lower semiconductor device comprises four vertices, and
wherein the plurality of upper semiconductor devices include four semiconductor devices vertically overlapping four vertices, respectively, of the upper surface of the first lower semiconductor device.

3. The semiconductor package of claim 1, further comprising a second redistribution structure on the molding layer, the second redistribution structure including a second redistribution insulating layer and a second redistribution pattern,
wherein the plurality of vertical connection conductors electrically connect the first redistribution pattern to the second redistribution pattern, and
wherein the plurality of upper semiconductor devices are each mounted on the second redistribution structure.

4. The semiconductor package of claim 3, further comprising a heat plate contact disposed between the heat dissipation plate and the upper surface of the first lower semiconductor device, the heat plate contact vertically penetrating the second redistribution insulating layer.

5. The semiconductor package of claim 4, wherein the heat plate contact comprises:
a plurality of heat dissipation pad layers spaced apart from each other in a vertical direction; and
heat dissipation via patterns extending between adjacent heat dissipation pad layers of the plurality of heat dissipation pad layers,
wherein, among the plurality of heat dissipation pad layers, the lowermost heat dissipation pad layer extends along the upper surface of the first lower semiconductor device.

6. The semiconductor package of claim 3, further comprising a second lower semiconductor device mounted on the first redistribution structure to be laterally spaced apart from the first lower semiconductor device,
wherein the second lower semiconductor device vertically overlaps any one of the plurality of upper semiconductor devices.

7. The semiconductor package of claim 6, wherein the second redistribution pattern comprises a conductive via pattern connected to a pad of the second lower semiconductor device provided at an upper surface of the second lower semiconductor device and extending in the molding layer.

8. The semiconductor package of claim 1, further comprising:
a plurality of conductive pads on an upper surface of the molding layer, the plurality of conductive pads being connected to the plurality of vertical connection conductors;
one or more dummy pads on the upper surface of the molding layer or the upper surface of the first lower semiconductor device, wherein the one or more dummy pads are not connected to the plurality of vertical connection conductors; and
a plurality of connection terminals on the plurality of conductive pads and the one or more dummy pads, the plurality of connection terminals being connected to a plurality of pads of the plurality of upper semiconductor devices.

9. The semiconductor package of claim 1, further comprising a dummy semiconductor substrate on the first redistribution structure to be laterally spaced apart from the first lower semiconductor device,
wherein the plurality of vertical connection conductors extend in the dummy semiconductor substrate.

10. The semiconductor package of claim 1, further comprising a stiffener attached on the molding layer.

11. The semiconductor package of claim 1, wherein the heat dissipation plate comprises a first segment between two upper semiconductor devices adjacent to each other in a first lateral direction among the plurality of upper semiconductor devices.

12. The semiconductor package of claim 11, wherein a part of the first segment of the heat dissipation plate vertically overlaps the first lower semiconductor device, and another part of the first segment of the heat dissipation plate does not vertically overlap the first lower semiconductor device.

13. The semiconductor package of claim 11, wherein the heat dissipation plate further comprises a second segment between two adjacent upper semiconductor devices in a second lateral direction among the plurality of upper semiconductor devices, and wherein the second lateral direction intersects the first lateral direction.

14. The semiconductor package of claim 1, wherein the first lower semiconductor device comprises a logic chip, and
wherein each of the plurality of upper semiconductor devices comprises a memory chip.

15. The semiconductor package of claim 1, wherein a first upper semiconductor device of the plurality of upper semiconductor devices is spaced apart from a second upper semiconductor device of the plurality of upper semiconductor devices in a first lateral direction with the heat dissipation plate therebetween,
wherein a ratio between a first length of the first lower semiconductor device and a second length of an overlapping region of the first lower semiconductor device vertically overlapping one of the plurality of upper semiconductor devices is between about 20% and about 40%, and
wherein the first length and the second length are lengths in the first lateral direction.

16. A semiconductor package comprising:
a lower package including a lower semiconductor device and a molding layer surrounding the lower semiconductor device;
a plurality of upper semiconductor devices on the lower package, each of the plurality of upper semiconductor devices vertically overlapping a different respective region of the lower semiconductor device; and
a heat dissipation plate on an upper surface of the lower semiconductor device, the heat dissipation plate laterally spaced apart from each of the plurality of upper semiconductor devices with a gap therebetween,
wherein the lower semiconductor device comprises at least one logic chip, and
wherein the plurality of upper semiconductor devices comprise four memory chips vertically overlapping four vertices of the upper surface of the lower semiconductor device, respectively.

17. The semiconductor package of claim 16, wherein the lower package further comprises:
a first redistribution structure under the molding layer and under the lower semiconductor device, the first redistribution structure including a first redistribution insulating layer and a first redistribution pattern;
a second redistribution structure on the molding layer and on the lower semiconductor device, the second redistribution structure including a second redistribution insulating layer and a second redistribution pattern; and
a plurality of vertical connection conductors in the molding layer and electrically connecting the first redistribution pattern to the second redistribution pattern.

18. The semiconductor package of claim 17, further comprising a heat plate contact between the heat dissipation plate and the upper surface of the lower semiconductor device, the heat plate contact being in a through hole of the second redistribution insulating layer,
wherein the thermal conductivity of the heat plate contact is greater than that of silicon, and
wherein the heat dissipation plate is thermally coupled to the lower semiconductor device through the heat plate contact.

19. The semiconductor package of claim 17, wherein the lower package comprises a first region and a second region surrounding the first region, and
wherein, when viewed in plan view, the lower semiconductor device is in the first region, and the plurality of vertical connection conductors are in the second region.

20. A semiconductor package comprising:
a first redistribution structure including a first redistribution insulating layer and a first redistribution pattern;
a lower semiconductor device mounted on a first region of the first redistribution structure;
a plurality of vertical connection conductors on a second region of the first redistribution structure, the plurality of vertical connection conductors being connected to the first redistribution pattern;
a molding layer on the first redistribution structure and surrounding the lower semiconductor device and the plurality of vertical connection conductors;
a second redistribution structure on the molding layer and the lower semiconductor device, the second redistribution structure including a second redistribution insulating layer and a second redistribution pattern, wherein the second redistribution pattern is electrically connected to the first redistribution pattern through the plurality of vertical connection conductors;
a heat plate contact within the second redistribution insulating layer and in contact with an upper surface of the lower semiconductor device;
a plurality of upper semiconductor devices mounted on the second redistribution structure and each vertically overlapping a different respective region of the lower semiconductor device; and
a heat dissipation plate attached on the heat plate contact and spaced apart from each of the plurality of upper semiconductor devices in a lateral direction with a gap therebetween,
wherein the upper surface of the lower semiconductor device comprises four vertices,
wherein the plurality of upper semiconductor devices comprise four semiconductor devices vertically overlapping the four vertices, respectively, of the upper surface of the lower semiconductor device,
wherein the lower semiconductor device comprises a logic chip, and
wherein the plurality of upper semiconductor devices comprise memory chips.
